(19) United States
(12) Patent Application Publication
(10) Pub. No.: US 2021/0139316 A1
(43) Pub. Date: May 13, 2021

(54) MICRO-ELECTROMECHANICAL ACTUATING DEVICE PROVIDING A MOVEMENT HAVING MULTIPLE DEGREES OF FREEDOM

(71) Applicant: Innovative Interface Laboratory Corp., Hsinchu (TW)

(72) Inventor: Yu-Wen Hsu, Taipei (TW)

(21) Appl. No.: 17/089,938

(22) Filed: Nov. 5, 2020

Related U.S. Application Data
(60) Provisional application No. 62/931,926, filed on Nov. 7, 2019.

(51) Int. Cl. B81B 3/00

(52) U.S. Cl. CPC B81B 3/0062; B81B 3/0027; B81B 2203/0136; B81B 2203/0307; B81B 3/0054

(57) ABSTRACT

A micro-electromechanical actuating device is disclosed. The micro-electromechanical actuating device includes a substrate having a cavity having a first area; a fixing portion disposed on the substrate; a first frame disposed around the fixing portion; and an elastic element connecting the first frame and the fixing portion, and causing the first frame to be suspended above the substrate, wherein the first frame has a projecting area onto the substrate; and the first area and the projecting area have an overlapping portion.

### CROSS-REFERENCE TO RELATED APPLICATION AND CLAIM OF PRIORITY

The application claims the benefit of the U.S. Provisional Application No. 62/931,926, filed on Nov. 7, 2019, at the USPTO, the disclosures of which are incorporated herein in their entirety by reference.

### FIELD OF THE INVENTION

The present invention relates to an actuating device, and more particularly to a micro-electromechanical actuating device providing a movement having multiple degrees of freedom.

### BACKGROUND OF THE INVENTION

In the case of the miniature camera, such as the camera device on the cellphone, the micro-electromechanical actuator has the potential to replace the voice coil motor to achieve, for example, the image stabilization and the autofocus. However, there are still some problems to be solved, such as the capacitance offset caused by the thermal stress generated in the SMD (Surface Mount Device) process and during the operation, increasing the efficiency of the electrical-mechanical energy conversion, the movable driving structure susceptible to the movement of other axes, and the reliability of the electrical connecting structure between the movable structure and the fixed structure. Please refer to FIG. 1, which is a side view of a micro-electromechanical actuator of the prior art. As shown in FIG. 1, a movable element 4 is connected to an anchor 2 via an elastic element 3, and the anchor 2 is fixed on a substrate 1. Because the anchor 2 is around the movable element 4, when the whole device suffers thermal stress, the substrate 1 is deformed. This causes the anchor 2 to squeeze the movable element 4 so that the position of the movable element 4 is affected. In addition, the structure of the micro-electromechanical actuator of the prior art requires a large amount of etching operations. However, due to the pursuit of the driving force and the requirement for the structure reduction, the distance between comb fingers of the actuator is getting closer, and the size of the comb finger is getting smaller. Therefore, the waste materials after etching easily get stuck between the comb fingers, and between the comb fingers and other structures.

In order to overcome the drawbacks in the prior art, a micro-electromechanical actuating device which can achieve the effect of the movement of multi-degree of freedom is disclosed. The particular design in the present invention not only solves the problems described above, but also is easy to implement. Thus, the present invention has utility for the industry.

### SUMMARY OF THE INVENTION

The present invention is to solve the shortcomings of the prior art, thereby improving the electro-mechanical converting efficiency and the manufacturing yield of the micro-electromechanical actuator, and further improving the reliability.

In accordance with one aspect of the present invention, a micro-electromechanical actuating device providing a movement having multiple degrees of freedom is disclosed. The micro-electromechanical actuating device comprises a substrate including a first cavity formed thereon; a first frame suspended above the substrate, and having a center point; a fixing portion disposed on the substrate, and surrounded by the first frame; a first micro-electromechanical actuator unit disposed between the first frame and the fixing portion, and configured to generate a first force in a first direction which does not pass through the center point; a second micro-electromechanical actuator unit disposed between the first frame and the fixing portion, and configured to generate a second force in a second direction which does not pass through the center point, wherein the first direction is parallel to the second direction, the first and the second forces jointly form a first resultant force in a first resultant direction passing through the center point; a third micro-electromechanical actuator unit disposed between the first frame and the fixing portion, and configured to generate a third force in a third direction which does not pass through the center point; and a fourth micro-electromechanical actuator unit disposed between the first frame and the fixing portion, and configured to generate a fourth force in a fourth direction which does not pass through the center point, wherein the third direction is parallel to the fourth direction, the third and the fourth force jointly form a second resultant force in a second resultant direction passing through the center point, there is a non-zero angle between the first resultant force direction and the second resultant force direction, and an upward projection of the first cavity at least partially covers areas of the first, the second, the third, and the fourth micro-electromechanical actuator units.

In accordance with another aspect of the present invention, a micro-electromechanical actuating device providing a movement of multiple degrees of freedom is disclosed. The micro-electromechanical actuating device comprises a fixing portion; a supporting structure surrounding the fixing portion, having a center point, and elastically connected to the fixing portion; a first actuating unit disposed between the fixing portion and the supporting structure, and having a first actuating direction passing through the center point; a second actuating unit disposed between the fixing portion and the supporting structure, and having a second actuating direction passing through the center point; and a third actuating unit disposed between the fixing portion and the supporting structure, and having a third actuating direction passing through the center point, wherein there is an angle between the first actuating direction and the second actuating direction, a force arm is formed between the third actuating direction and the center point, and a first cavity is formed under the first, the second, and the third actuating units.

In accordance with a further aspect of the present invention, a micro-electromechanical actuating device is disclosed. The micro-electromechanical actuating device comprises a substrate having a cavity having a first area; a fixing portion disposed on the substrate; a first frame disposed around the fixing portion; and an elastic element connecting the first frame and the fixing portion, and causing the first frame to be suspended above the substrate, wherein: the first frame has a projecting area onto the substrate; and the first area and the projecting area have an overlapping portion.

In order to achieve the requirements for enhancing the electrical-mechanical conversion, enhancing the reliability of the electrical connection and the wire bonding, and the structure reduction, the distance between the comb fingers of the actuator is getting closer so that the waste materials after etching easily get stuck between the comb fingers, and between the comb fingers and other structures. In order to make the waste materials easy to discharge, it is necessary to increase the distance between the comb finger and the substrate as much as possible, i.e. removing the material of the substrate in the direction away from the comb finger. When the distance is increased to the maximum, all the material of the substrate is removed, i.e. hollowing out the substrate. In other words, in the present invention, a hollow structure is formed on the substrate. The hollow structure is usually a through structure. That is, there is no object under the comb fingers of the actuator. Therefore, the waste materials after etching can be directly discharged from the hollow structure, or the waste materials can be found further away from the comb finger after they leaves the comb finger, instead of staying too close to the comb finger, thereby reducing the probability of the waste materials staying on or returning to the comb finger. In addition, a jig for the wire bonding is further used to support the movable part of the actuator of the present invention from below during the wire bonding so as to enhance the yield and the reliability of the wire bonding.

The above objectives and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a side view of a micro-electromechanical actuator of the prior art;

FIG. 2 is a top view of a micro-electromechanical actuator according to an embodiment of the present invention;

FIG. 3 is a cross-sectional view of FIG. 2 along the dotted line AA;

FIGS. 4-1 and 4-2 show the assembling state of the present invention;

FIG. 5 is a partially enlarged view of FIG. 2; and

FIG. 6 is a top view of a micro-electromechanical actuator according to another embodiment of the present invention.

### DETAILED DESCRIPTION OF THE PREFERRED EMBODIMENTS

The present invention will now be described more specifically with reference to the following embodiments. It is to be noted that the following descriptions of preferred embodiments of this invention are presented herein for the purposes of illustration and description only; they are not intended to be exhaustive or to be limited to the precise form disclosed.

Please refer to FIGS. 2 and 3 simultaneously, wherein FIG. 2 is a top view of a micro-electromechanical actuator according to an embodiment of the present invention, and FIG. 3 is a cross-sectional view of FIG. 2 along the dotted line AA. The micro-electromechanical actuator includes a substrate 1, a first frame 4, and a second frame 6. The first frame 4 and the second frame 6 are formed on the substrate 1, and the second frame 6 surrounds the first frame 4. The first frame 4 serves as a supporting structure, and the second frame 6 serves as a peripheral structure. The first frame 4 serves as a movable element, and is connected to a fixing portion 2 via elastic elements 3. The fixing portion 2 can be an anchor which is connected to the substrate 1. It can be clearly seen in FIG. 2 that the present invention adopts a central fixing portion (anchor) structure, and each elastic element 3 is connected to four corners of the first frame 4. Therefore, when the elastic elements 3 suffer the compressing force, the restoring force thereof is applied to the corners of the first frame 4, thereby expand the first frame 4 to maintain the original shapes of edges of the first frame 4, which are usually perfectly straight. The present invention further includes four micro-electromechanical actuator units 5. Each micro-electromechanical actuator unit has a first comb finger unit 5a fixed on the anchor 2, i.e. indirectly fixed on the substrate 1. Each micro-electromechanical actuator unit 5 further includes a first counter comb finger unit 5a′ fixed on the first frame 4. That is, the first comb finger unit 5a and the first counter comb finger unit 5a′ are disposed in pairs. The comb fingers of the first comb finger unit 5a directly face the finger slits of the first counter comb finger unit 5a′. Similarly, the comb fingers of the first counter comb finger unit 5a′ directly face the finger slits of the first comb finger unit 5a. When the electrostatic force is generated, the first comb finger unit 5a and the first counter comb finger unit 5a′ attract each other so that the comb fingers of the first comb finger unit 5a and those of the first counter comb finger unit 5b′ are staggered. The first comb finger unit 5a and the first counter comb finger unit 5a′ serve as an actuating unit. For the lower micro-electromechanical actuator unit 5, when the electrostatic force is generated through electrifying, the first comb finger unit 5a and the first counter comb finger unit 5a′ attract each other, thereby causing the first frame 4 to move upward. In addition, because the electrostatic force passes through a center point RA of the first frame 4, the first frame 4 does not rotate. For the same reason, when the upper micro-electromechanical actuator unit 5 is electrified to generate the electrostatic force, the first frame 4 moves downward; when the left micro-electromechanical actuator unit 5 is electrified to generate the electrostatic force, the first frame 4 moves to the right; and when the right micro-electromechanical actuator unit 5 is electrified to generate the electrostatic force, the first frame 4 moves to the left. Moreover, the micro-electromechanical actuator unit 5 further includes a sensing comb finger unit 5b. The sensing comb finger unit 5b is located opposite the first counter comb finger unit 5a′ to sense the capacitance value between the first counter comb finger unit 5a′ and the sensing comb finger unit 5b when the first frame 4 moves. Then, the capacitance value is converted to the distance between the first counter comb finger unit 5a′ and the sensing comb finger unit 5b, thereby confirming the distance that the first frame 4 moves. The sensing comb finger unit 5b and the first counter comb finger unit 5a′ serve as another actuating unit, and the first counter comb finger unit 5a′ serves as a position sensing capacitor. In addition, the first frame 4 usually serves as a carrier, on which an electronic element (not shown) is fixed. Therefore, for electrical connection, a plurality of bonding pads 40 are further disposed on the first frame 4. For the same reason, the substrate 1 also has a plurality of bonding pads 10, and the second frame 6 also has a plurality of bonding pads 60. The purposes of the bonding pads 40, 10, 60 will be illustrated in FIGS. 4-1 and 4-2. Furthermore, in order to electrically connect the first frame 4 with the second frame 6, and also to enable the first frame 4 to move freely in the second frame 6, the first frame 4 is electrically connected to the second frame 6 via a plurality of flexible elements 7. Each flexible element 7 is formed together with the first frame 4 and the second frame 6, and usually mainly composed of silicon with a conductive metal layer in between. When viewed from above, each flexible element 7 is roughly zigzag from left to right, but its thickness is roughly identical to that of the first frame 4. Through a larger thickness of each flexible element 7, the effect of immunity in the Z-axis direction is achieved. In addition, please see the lower left corners of the first frame 4, the second frame 6, and the substrate 1. In the present invention, in order to prevent the first frame 4 and the second frame 6 from being damaged due to accidental shaking, excessive displacement distance, and other uncertain conditions, a spacer 41 is disposed on the first frame 4. The spacer 41 is usually a protrusion to prevent the first frame 4 and the second frame 6 from being too close to cause the flexible elements 7 to be excessively squeezed. Through the spacer 41, a gap can remain between the first frame 4 and the second frame 6. In addition, in order to absorb the impact force, a cushion is further disposed on the second frame 6 at the position corresponding to the spacer 41. The cushion is formed via a cushioning space 61 on the second frame 6. The cushioning space 61 is a through hole so that the cushion 62 can be formed. Therefore, when the spacer 41 hits the cushion 62, the material at the position of the cushion 62 can be appropriately deformed toward the cushion space 61 to absorb the impact force.

Please refer to FIG. 3, which is a cross-sectional view of FIG. 2 along the dotted line AA. As shown in FIG. 3, the substrate has cavities, whose positions can be under the micro-electromechanical actuator unit 5, or under both of the first frame 4 and the flexible elements 7, or under all of the micro-electromechanical actuator unit 5, the first frame 4, and the flexible elements 7. For ease of description, the cavity located under the micro-electromechanical actuator unit 5 is referred to as a first cavity 11, and the cavity located under both the first frame 4 and the flexible elements 7 is referred to as a second cavity 12. Moreover, in order to achieve the effect of eliminating the waste materials and residues after etching, for the first cavity 11, the upward (i.e. toward the first frame 4) projecting area thereof at least partially covers the micro-electromechanical actuator unit 5. In addition, each side of the upward projecting area of the first cavity 11 can overlap each side of the area occupied by all comb fingers of the micro-electromechanical actuator unit 5, or the perimeter of the upward projecting area of the first cavity 11 is slightly larger or smaller than that of the area occupied by all comb fingers of the micro-electromechanical actuator unit 5. For the same reason, the upward (i.e. toward the first frame 4) projecting area of the second cavity 12 at least partially covers the flexible elements 7 and the first frame 4. Furthermore, each side of the upward projecting area of the second cavity 12 can overlap each side of the area occupied by all flexible elements 7 at a certain side of the first frame 4, or the perimeter of the upward projecting area of the second cavity 12 is slightly larger or smaller than that of the area occupied by all flexible elements 7 at the certain side of the first frame 4. As mentioned above, due to the miniaturization of the size of the comb finger, the width of the finger slit between the comb fingers is very small. In addition, when the first comb finger unit 5a and the first counter comb finger unit 5a′ are staggered, the space at the finger slit of the first comb finger unit 5a becomes even narrower, because a large part thereof is taken up by the first counter comb finger unit 5a′; similarly, the space at the finger slit of the first counter comb finger unit 5a′ also becomes even narrower, because a large part thereof is taken up by the first comb finger unit 5a. Due to the existence of the first cavity 11, the waste materials and residues after etching the comb fingers will fall into the first cavity 11 and then be discharged, or at least stay in the first cavity 11 and away from the comb fingers. This enables the probability of the waste materials and residues staying between the finger slits or between the comb fingers and the substrate to be greatly reduced so that the production yield is greatly enhanced. For the same reason, because each flexible element 7 must be quite flexible, i.e. very easy to be stretched and squeezed, and its elastic restoring force is extremely low so as not to affect the movement of the first frame 4, the structure of each flexible element 7 is also extremely small. Therefore, the gap between the zigzag structures of two adjacent flexible elements 7 is also very narrow. If the waste materials and residues after etching remain, the softness of each flexible element 7 will be greatly reduced. Hence, through the disposition of the second cavity 12 of the present invention, the waste materials and residues after etching the flexible elements 7 will fall into the second cavity 12 and then be discharged, or at least stay in the second cavity 12 and away from the flexible elements 7. This enables the probability of the waste materials and residues staying in the gap between the zigzag structures of two adjacent flexible elements 7 or between each flexible element 7 and the substrate 1 to be greatly reduced so that the production yield is greatly enhanced. Furthermore, the bonding pads 10, 40, 60 are disposed on the substrate 1, the first frame body 4, and the second frame body 6 respectively. The purposes of the bonding pads 10, 40, 60 will be illustrated in FIGS. 4-1 and 4-2.

Please refer to FIGS. 4-1 and 4-2, which show the assembling state of the present invention. The first comb finger units 5a of the micro-electromechanical actuator units 5 (please refer to FIG. 2) are all fixed on the substrate 1 via the anchor 2. In order to avoid assembling failure or even structural damage due to the shaking of the first frame 4 during the assembling of the electronic element 8 and the wire bonding 70, a supporting body 100 is used as a jig. Supporting protrusions 100″ of the supporting body 100″ pass through the second cavity 12 to support the first frame 4, and the substrate 1 is directly placed on the supporting surface 100′. In this way, the stability of the overall structure during the assembling of the electronic element 8 and the wire bonding 70 can be ensured. Through the wire bonding 70, the bonding pads 80 are electrically connected to the bonding pads 40 of the first frame 4. In this way, signals of the electronic element 8 can be transmitted outwards, or external commands can be transmitted into the electronic element 8. Moreover, the bonding pads 40 are electrically connected to the bonding pads 60 via the flexible elements 7, the bonding pads 60 are electrically connected to the bonding pads 10 via the wire bonding process, and then the bonding pads 10 are electrically connected to the outside. For the sake of simplicity of the drawings, the first cavity 11 in FIG. 3 is not drawn in FIGS. 4-1 and 4-2.

Please refer to FIG. 5, which is a partially enlarged view of FIG. 2. FIG. 5 mainly shows the left micro-electromechanical actuator unit 5 of the entire device in FIG. 2 and its surrounding elements. The first comb finger unit 5a of the micro-electromechanical actuator unit 5 is fixed on the anchor 2, and the first counter comb finger unit 5a′ is fixed on the first frame body 4 and corresponding to the first comb finger unit 5a. As for the sensing comb finger unit 5b, it is located opposite to the first counter comb finger unit 5a′. The effects of the above comb finger units 5a, 5a′, 5b are not repeated here. Because the first frame 4 of this embodiment can move up and down or left and right, it is possible that the first counter comb finger unit 5a′ collides with the first comb finger unit 5a and the sensing comb finger unit 5b, thereby causing damage. In order to avoid this phenomenon, in the present invention, a constraint anchor 2′ (constraint fixing portion) and a constraint hinge 31 are disposed near each micro-electromechanical actuator unit 5, and a decoupling hinge 32 is disposed between the first frame 4 and the first counter comb finger unit 5a′. The decoupling hinge 32 is fixed to the constraint hinge 31 via a decoupling point 30. Take FIG. 5 as an example, the first counter comb finger unit 5a′ is only allowed to move left and right, i.e. moving parallel to the forward and reverse directions of the X-axis, and moving forward and reversely along the finger direction of the first counter comb finger unit 5a′. Moreover, the first counter comb finger unit 5a′ must be immune to the movement parallel to the Y-axis direction, i.e. not moving in the arranging direction of the first counter comb finger unit 5a′. Similarly, the right micro-electromechanical actuator unit 5 of the entire device in FIG. 2 operates in the same way. That is, the micro-electromechanical actuator unit 5 which controls the first frame 4 to move left and right must be immune to the Y-axis direction. Furthermore, the micro-electromechanical actuator unit 5 which controls the first frame 4 to move up and down, i.e. the upper and lower micro-electromechanical actuator units 5 in FIG. 2, must be immune to the X-axis direction. Therefore, the constraint hinge 31 must be immune to the arranging direction of the first counter comb finger units 5a′. According to FIG. 5, the arranging direction of the first counter comb finger units 5a′ is an up-and-down arranging direction. However, because the first counter comb finger unit 5a′ must be able to move horizontally along the finger direction of the first counter comb finger unit 5a′, i.e. moving left and right or in the X-axis direction according to the left micro-electromechanical actuator unit 5 in FIG. 5, the constraint hinge 31 must be able to generate the elastic deformation along the finger direction of the first counter comb finger unit 5a′. Thus, the anchor 2′ must be as far away from the decoupling point 30 as possible. For the upper and lower decoupling points 30 for the first counter comb finger unit 5a′ in FIG. 5, the midpoint thereof is the position where the constraint anchor 2′ is disposed. The upper decoupling point 30, the lower decoupling point 30, and the constraint anchor 2′ are aligned in a straight line parallel to the arranging direction of the first counter comb finger unit 5a′ (the Y-axis direction). Hence, the size of the constraint hinge 31 in the finger direction of the first counter comb finger unit 5a′ (the X-axis direction) is extremely short. This causes the constraint hinge 31 to have an extremely high rigidity in the direction parallel to the arranging direction of the first counter comb finger unit 5a′ (the Y-axis direction). Therefore, when the first frame 4 moves up or down, the constraint hinge 31 can pull the decoupling point 30 tight without moving, and only the decoupling hinge 32 bends under the driving of the first frame 4. However, because the upper and lower decoupling points 30 are at a considerable distance from the constraint anchor 2′ in the Y-axis direction, the constraint hinge 31 has considerable elasticity in the X-axis direction. Hence, when the first counter comb finger unit 5a′ moves along the finger direction, the constraint hinge 31 can be pulled by the decoupling point 30 and bent. For the same reason, for the decoupling hinge 32, because it needs to bend in the direction parallel to the arranging direction of the first counter comb finger unit 5a′, it needs to have a longer characteristic length in the direction parallel to the finger direction of the first counter comb finger unit 5a′ to increase the elasticity. Oppositely, the decoupling hinge 32 cannot bend in the direction parallel to the finger direction of the first counter comb finger unit 5a′, so its characteristic length in the direction parallel to the arranging direction of the first counter comb finger unit 5a′ must be very short. That is, the first connecting point 30a between the decoupling hinge 32 and the first frame 4, the second connecting point 30b between the decoupling hinge 32 and the first counter comb finger unit 5a′, and the decoupling point 30 are aligned in a straight line parallel to the finger direction of the first counter comb finger unit 5a′ so that the decoupling hinge 31 can be immune to the bending generated by receiving the force parallel to the finger direction of the first counter comb finger unit 5a′. Therefore, when the first relative counter finger 5a′ is pulled to the right, the decoupling hinge 32 can be pulled to the right by the first relative counter finger 5a′ without deformation so that the transmission of the pulling force is not delayed, or the pulling force will not be absorbed due to the deformation of the decoupling hinge 32.

Please continue to refer to FIG. 5. In order to appropriately increase the bending ability of the constraint hinge 31 in the direction parallel to the finger direction of the first counter comb finger unit 5a′, i.e. the flexibility, the constraint hinge 31 has a folded structure. However, the folded structure of the constraint hinge 31 is still fixed to the constraint anchor V and the decoupling point 30 in the direction parallel to the arranging direction of the first counter comb finger unit 5a′. For the same reason, in order to appropriately increase the bending ability of the decoupling hinge 31 in the direction parallel to the arranging direction of the first counter comb finger unit 5a′, i.e. the flexibility, the decoupling hinge 31 also has a folded structure. However, the folded structure of the decoupling hinge 31 is still fixed to the decoupling point 30 and the first frame 4 in the direction parallel to the finger direction of the first counter comb finger unit 5a′.

Please refer to FIG. 6, which is a top view of a micro-electromechanical actuator according to another embodiment of the present invention. As shown in FIG. 6, the micro-electromechanical actuator has a plurality of micro-electromechanical actuator units 5, and each micro-electromechanical actuator unit 5 has a plurality of comb finger structures. First, for the X-axis direction, a first comb finger unit 501, a second comb finger unit 502, a third comb finger unit 503, and a fourth comb finger unit 504 are connected to an anchor 2. A positive X-axis direction sensing comb finger unit 5b+x is disposed between the first comb finger unit 501 and the second comb finger unit 504, and a negative X-axis direction sensing comb finger unit 5b−x is disposed between the third comb finger unit 503 and the fourth comb finger unit 504. All comb finger units 501, 502, 503, 504, 5b+x, 5b−x are fixed to a substrate via the anchor 2 (please refer to FIG. 3). It can be seen in FIG. 6 that the electrostatic force directions of the first comb finger unit 501, the second comb finger unit 502, the third comb finger unit 503, and the fourth comb finger unit 504 all do not pass through the center point RA (rotating axis). However, because the first comb finger unit 501 and the second comb finger unit 502 are symmetrically disposed, the resultant force of the respective electrostatic forces of the first comb finger unit 501 and the second comb finger unit 502 passes through the center point RA. Similarly, because the third comb finger unit 503 and the fourth comb finger unit 504 are also symmetrically disposed, the resultant force of the respective electrostatic forces of the third comb finger unit 503 and the fourth comb finger unit 504 also passes through the center point RA. Therefore, when intending to enable the first frame 4 to move toward the positive direction of the X-axis, the first comb finger unit 501 and the second comb finger unit 502 simultaneously generate electrostatic forces to attract the first counter comb finger unit 5a′. At the same time, an inductive capacitance is generated between the positive X-axis direction sensing comb finger unit 5b+x and the first counter comb finger unit 5a′ so that the moving distance of the first frame 4 can be derived. Similarly, when intending to enable the first frame 4 to move toward the negative direction of the X-axis, the third comb finger unit 503 and the fourth comb finger unit 504 simultaneously generate electrostatic forces to attract the first counter comb finger unit 5a′. At the same time, an inductive capacitance is generated between the negative X-axis direction sensing comb finger unit 5b−x and the first counter comb finger unit 5a′ so that the moving distance of the first frame 4 can be derived. In addition, the embodiment of FIG. 6 also has the constraint anchor 2′, the constraint hinge 31, the decoupling hinge 32, the decoupling point 30, the first connecting point 30a, and the second connecting point 30b. The related connecting relationships among the constraint anchor 2′, the constraint hinge 31, the decoupling hinge 32, and the decoupling point 30 as well as the functions thereof have been described in FIG. 5, and will not be repeated here.

Please continue to refer to FIG. 6. For the Y-axis direction, a fifth comb finger unit 505, a sixth comb finger unit 506, a seventh comb finger unit 507, and a eighth comb finger unit 504 are connected to the anchor 2. A positive Y-axis direction sensing comb finger unit 5b+y is disposed between the seventh comb finger unit 507 and the eighth comb finger unit 508, and a negative Y-axis direction sensing comb finger unit 5b−y is disposed between the fifth comb finger unit 505 and the sixth comb finger unit 506. All comb finger units 505, 506, 507, 508, 5b+y, 5b−y are fixed to the substrate via the anchor 2 (please refer to FIG. 3). It can be seen in FIG. 6 that the electrostatic force directions of the fifth comb finger unit 505, the sixth comb finger unit 506, the seventh comb finger unit 507, and the eighth comb finger unit 508 all do not pass through the center point RA (rotating axis). However, because the fifth comb finger unit 505 and the sixth comb finger unit 506 are symmetrically disposed, the resultant force of the respective electrostatic forces of the fifth comb finger unit 505 and the sixth comb finger unit 506 passes through the center point RA. Similarly, because the seventh comb finger unit 507 and the eighth comb finger unit 508 are also symmetrically disposed, the resultant force of the respective electrostatic forces of the seventh comb finger unit 507 and the eighth comb finger unit 508 also passes through the center point RA. Therefore, when intending to enable the first frame 4 to move toward the positive direction of the Y-axis, the seventh comb finger unit 507 and the eighth comb finger unit 508 simultaneously generate electrostatic forces to attract the first counter comb finger unit 5a′. At the same time, an inductive capacitance is generated between the positive Y-axis direction sensing comb finger unit 5b+y and the first counter comb finger unit 5a′ so that the moving distance of the first frame 4 can be derived. Similarly, when intending to enable the first frame 4 to move toward the negative direction of the Y-axis, the fifth comb finger unit 505 and the sixth comb finger unit 506 simultaneously generate electrostatic forces to attract the first counter comb finger unit 5a′. At the same time, an inductive capacitance is generated between the negative Y-axis direction sensing comb finger unit 5b−y and the first counter comb finger unit 5a′ so that the moving distance of the first frame 4 can be derived. In addition, because the sensing comb finger and the actuating comb finger are both the application of the sensing capacitor, actually the functions of the sensing comb finger and the actuating comb finger can be replaced via software to increase the flexibility of use.

Please continue to refer to FIG. 6. Because the respective electrostatic forces of the first to the eighth comb finger units 501˜508 all do not pass through the center point RA, if intending to make the first frame 4 rotate, in principle it is only necessary that one of the first to the eighth comb finger units 501˜508 generates the electrostatic force, and the first frame 4 can rotate. For example, for the first, the third, the fifth, and the seventh comb finger units 501, 503, 505, 507, when one of them generates the electrostatic force, the first frame 4 can rotate clockwise. Certainly, in order to average forces, it is usually more appropriate to apply forces with the comb finger units in the diagonal direction; that is, the first comb finger unit 501 and the third comb finger unit 503 both generate electrostatic forces, or the fifth comb finger unit 505 and the seventh comb finger unit 507 both generate electrostatic forces. If in order to increase the driving force more quickly, the first comb finger unit 501, the third comb finger unit 503, the fifth comb finger unit 505, and the seventh comb finger unit 507 can all generate electrostatic forces to achieve the above effect. Similarly, for the second, the fourth, the sixth, and the eighth comb finger units 502, 504, 506, 508, when one of them generates the electrostatic force, the first frame 4 can rotate counterclockwise. Certainly, in order to average forces, it is usually more appropriate to apply forces with the comb finger units in the diagonal direction; that is, the second comb finger unit 502 and the fourth comb finger unit 504 both generate electrostatic forces, or the sixth comb finger unit 506 and the eighth comb finger unit 508 both generate electrostatic forces. If in order to increase the driving force more quickly, the second comb finger unit 502, the fourth comb finger unit 504, the sixth comb finger unit 506, and the eighth comb finger unit 508 can all generate electrostatic forces to achieve the above effect. Furthermore, the underside of each micro-electromechanical actuator unit 5 of the embodiment in FIG. 6 can have a cavity as shown in FIGS. 2 and 3 so that the waste materials and residues after etching can be discharged. The specific relationship between the cavity and the comb fingers or the flexible elements is as shown in FIG. 3 and its descriptions, and will not be repeated here.

Please continue to refer to FIG. 6. In this embodiment, the first frame 4 can also move obliquely on the XY plane. For example, for the movement toward the upper right direction, it can be achieved by the attractions generated by the pair of the first comb finger unit 501 and the eighth comb finger unit 508, or by the attractions generated by the pair of the second comb finger unit 502 and the seventh comb finger unit 507. Certainly, the movement toward the upper right direction can also be achieved by the attractions generated by the pair of the first comb finger unit 501 and the eighth comb finger unit 508, simultaneously with the attractions generated by the pair of the second comb finger unit 502 and the seventh comb finger unit 507; that is, the four comb finger units 501, 508, 502, 507 simultaneously generate electrostatic forces. Similarly, for the movement toward the lower left direction, the purpose of oblique movement is achieved by the third, the fourth, the fifth, and the sixth comb finger units 503, 504, 505, 506. As for the movement toward the upper left direction and the lower right direction, they are achieved in a similar fashion, and will not be repeated here.

In summary, through the embodiment as shown in FIG. 6, the present invention can achieve a micro-electromechanical actuating device providing a movement having multiple degrees of freedom on the plane, i. e. the horizontal movement on the XY plane (i.e. including the horizontal movement in the X-axis direction, the horizontal movement in the Y-axis direction, and the oblique and horizontal movement), and the rotation in the Z-axis direction. Through the comb finger units of the micro-electromechanical actuator anchored in the center, facing four sides, and disposed in pairs, although the directions of the electrostatic forces of the respective comb finger units of the micro-electromechanical actuator all do not pass through the center point, the supporting structure (the first frame, the inner frame, or the moving frame) can move horizontally as long as two comb finger units at the same side simultaneously operate with the same force. If only a single comb finger unit generates the electrostatic force, because the direction of the electrostatic force thereof does not pass through the center point, a force arm is formed between the electrostatic force and the center point, thereby generating a deflecting torque. In addition, by disposing a cavity on the substrate, the waste materials and residues generated during the manufacture of the actuator can be more easily discharged from the finger slits of the comb finger unit of the actuator, and from the place between the comb fingers and the substrate. Otherwise, the waste materials and residues are at least kept away from the comb fingers of the actuator so as not to affect the operation of the actuator so that the comb fingers of the actuator can be made smaller and denser, thereby enhancing the electro-mechanical converting efficiency, greatly increasing the driving force of the electrostatic force, and enhancing the yield rate. Moreover, a jig for the wire bonding is further used to support the movable part of the actuator of the present invention from below during the wire bonding so as to enhance the yield and the reliability of the wire bonding. It can be seen that the present invention has an outstanding contribution to this technical field.

### EMBODIMENTS

1. A micro-electromechanical actuating device providing a movement having multiple degrees of freedom, comprising a substrate including a first cavity formed thereon; a first frame suspended above the substrate, and having a center point; a fixing portion disposed on the substrate, and surrounded by the first frame; a first micro-electromechanical actuator unit disposed between the first frame and the fixing portion, and configured to generate a first force in a first direction which does not pass through the center point; a second micro-electromechanical actuator unit disposed between the first frame and the fixing portion, and configured to generate a second force in a second direction which does not pass through the center point, wherein the first direction is parallel to the second direction, the first and the second forces jointly form a first resultant force in a first resultant direction passing through the center point; a third micro-electromechanical actuator unit disposed between the first frame and the fixing portion, and configured to generate a third force in a third direction which does not pass through the center point; and a fourth micro-electromechanical actuator unit disposed between the first frame and the fixing portion, and configured to generate a fourth force in a fourth direction which does not pass through the center point, wherein the third direction is parallel to the fourth direction, the third and the fourth force jointly form a second resultant force in a second resultant direction passing through the center point, there is a non-zero angle between the first resultant force direction and the second resultant force direction, and an upward projection of the first cavity at least partially covers areas of the first, the second, the third, and the fourth micro-electromechanical actuator units.

2. The micro-electromechanical actuating device of Embodiment 1, further comprising a second frame surrounding the first frame.

3. The micro-electromechanical actuating device of any one of Embodiments 1-2, wherein the first frame moves within the second frame through at least one of the first, the second, the third, and the fourth forces.

4. The micro-electromechanical actuating device of any one of Embodiments 1-3, wherein the first frame is electrically connected to the second frame via a plurality of flexible elements.

5. The micro-electromechanical actuating device of any one of Embodiments 1-4, wherein a plurality of bonding pads are disposed at a peripheral of the first frame, and adjacent to and electrically connected to the flexible elements.

6. The micro-electromechanical actuating device of any one of Embodiments 1-5, wherein the substrate further includes a second cavity formed thereon, and located under the bonding pads.

7. A micro-electromechanical actuating device providing a movement of multiple degrees of freedom, comprising a fixing portion; a supporting structure surrounding the fixing portion, having a center point, and elastically connected to the fixing portion; a first actuating unit disposed between the fixing portion and the supporting structure, and having a first actuating direction passing through the center point; a second actuating unit disposed between the fixing portion and the supporting structure, and having a second actuating direction passing through the center point; and a third actuating unit disposed between the fixing portion and the supporting structure, and having a third actuating direction passing through the center point, wherein there is an angle between the first actuating direction and the second actuating direction, a force arm is formed between the third actuating direction and the center point, and a first cavity is formed under the first, the second, and the third actuating units.

8. The micro-electromechanical actuating device of Embodiment 7, further comprising a substrate and an elastic element elastically connecting the supporting structure and the fixing portion.

9. The micro-electromechanical actuating device of any one of Embodiments 7-8, wherein the fixing portion is fixed on the substrate; and the supporting structure is indirectly fixed on the substrate via the elastic element and the fixing portion.

10. The micro-electromechanical actuating device of any one of Embodiments 7-9, wherein the first cavity is formed on the substrate.

11. The micro-electromechanical actuating device of any one of Embodiments 7-10, further comprising a peripheral structure disposed on the substrate, having a relative displacement with the supporting structure, and electrically connected to the supporting structure via a plurality of flexible elements.

12. The micro-electromechanical actuating device of any one of Embodiments 7-11, wherein a plurality of bonding pads are disposed on the supporting structure adjacent to the flexible elements; the substrate has a second cavity; and an upward projection of the second cavity at least covers a part of the bonding pads and a part of the flexible elements.

13. The micro-electromechanical actuating device of any one of Embodiments 7-12, further comprising a position sensing capacitor disposed between the fixing portion and the supporting structure, and having a sensing direction parallel to one of the first, the second, and the third actuating directions.

14. A micro-electromechanical actuating device, comprising a substrate having a cavity having a first area; a fixing portion disposed on the substrate; a first frame disposed around the fixing portion; and an elastic element connecting the first frame and the fixing portion, and causing the first frame to be suspended above the substrate, wherein the first frame has a projecting area onto the substrate; and the first area and the projecting area have an overlapping portion.

15. The micro-electromechanical actuating device of Embodiment 14, further comprising a first comb finger unit fixed on the fixing portion, and having a first finger direction; and a first counter comb finger unit disposed on the first frame, and being in pair with the first comb finger unit.

16. The micro-electromechanical actuating device of any one of Embodiments 14-15, further comprising a decoupling hinge disposed between the first counter comb finger unit and the first frame, connected to the substrate, and immune to a deformation parallel to the first finger direction.

17. The micro-electromechanical actuating device of any one of Embodiments 14-16, further comprising a constraint hinge connected to and disposed between the substrate and the decoupling hinge, and generating an elastic deformation along the first finger direction.

18. The micro-electromechanical actuating device of any one of Embodiments 14-17, wherein a first connecting point between the constraint hinge and the decoupling hinge is a decoupling point; the decoupling point, a second connecting point between the decoupling hinge and the first counter comb finger unit, and a third connecting point between the decoupling hinge and the first frame are aligned in a first straight line; and the first straight line is parallel to the first finger direction.

19. The micro-electromechanical actuating device of any one of Embodiments 14-18, wherein the constraint hinge is connected to a constraint anchor, and connected to the substrate via the constraint anchor.

20. The micro-electromechanical actuating device of any one of Embodiments 14-19, wherein a connecting point between the constraint hinge and the decoupling hinge is a decoupling point, and a second straight line formed by linking the constraining anchor with the decoupling point is perpendicular to the first finger direction.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A micro-electromechanical actuating device providing a movement having multiple degrees of freedom, comprising:
a substrate including a first cavity formed thereon;
a first frame suspended above the substrate, and having a center point;
a fixing portion disposed on the substrate, and surrounded by the first frame;
a first micro-electromechanical actuator unit disposed between the first frame and the fixing portion, and configured to generate a first force in a first direction which does not pass through the center point;
a second micro-electromechanical actuator unit disposed between the first frame and the fixing portion, and configured to generate a second force in a second direction which does not pass through the center point, wherein the first direction is parallel to the second direction, the first and the second forces jointly form a first resultant force in a first resultant direction passing through the center point;
a third micro-electromechanical actuator unit disposed between the first frame and the fixing portion, and configured to generate a third force in a third direction which does not pass through the center point; and
a fourth micro-electromechanical actuator unit disposed between the first frame and the fixing portion, and configured to generate a fourth force in a fourth direction which does not pass through the center point, wherein the third direction is parallel to the fourth direction, the third and the fourth force jointly form a second resultant force in a second resultant direction passing through the center point, there is a non-zero angle between the first resultant force direction and the second resultant force direction, and an upward projection of the first cavity at least partially covers areas of the first, the second, the third, and the fourth micro-electromechanical actuator units.

2. The micro-electromechanical actuating device as claimed in claim 1, further comprising a second frame surrounding the first frame.

3. The micro-electromechanical actuating device as claimed in claim 2, wherein the first frame moves within the second frame through at least one of the first, the second, the third, and the fourth forces.

4. The micro-electromechanical actuating device as claimed in claim 3, wherein the first frame is electrically connected to the second frame via a plurality of flexible elements.

5. The micro-electromechanical actuating device as claimed in claim 4, wherein a plurality of bonding pads are disposed at a peripheral of the first frame, and adjacent to and electrically connected to the flexible elements.

6. The micro-electromechanical actuating device as claimed in claim 5, wherein the substrate further includes a second cavity formed thereon, and located under the bonding pads.

7. A micro-electromechanical actuating device providing a movement of multiple degrees of freedom, comprising:
a fixing portion;
a supporting structure surrounding the fixing portion, having a center point, and elastically connected to the fixing portion;
a first actuating unit disposed between the fixing portion and the supporting structure, and having a first actuating direction passing through the center point;
a second actuating unit disposed between the fixing portion and the supporting structure, and having a second actuating direction passing through the center point; and
a third actuating unit disposed between the fixing portion and the supporting structure, and having a third actuating direction passing through the center point, wherein there is an angle between the first actuating direction and the second actuating direction, a force arm is formed between the third actuating direction and the center point, and a first cavity is formed under the first, the second, and the third actuating units.

8. The micro-electromechanical actuating device as claimed in claim 7, further comprising a substrate and an elastic element elastically connecting the supporting structure and the fixing portion.

9. The micro-electromechanical actuating device as claimed in claim 8, wherein:
the fixing portion is fixed on the substrate; and
the supporting structure is indirectly fixed on the substrate via the elastic element and the fixing portion.

10. The micro-electromechanical actuating device as claimed in claim 9, wherein the first cavity is formed on the substrate.

11. The micro-electromechanical actuating device as claimed in claim 10, further comprising a peripheral structure disposed on the substrate, having a relative displacement with the supporting structure, and electrically connected to the supporting structure via a plurality of flexible elements.

12. The micro-electromechanical actuating device as claimed in claim 11, wherein:
a plurality of bonding pads are disposed on the supporting structure adjacent to the flexible elements;
the substrate has a second cavity; and
an upward projection of the second cavity at least covers a part of the bonding pads and a part of the flexible elements.

13. The micro-electromechanical actuating device as claimed in claim 7, further comprising a position sensing capacitor disposed between the fixing portion and the supporting structure, and having a sensing direction parallel to one of the first, the second, and the third actuating directions.

14. A micro-electromechanical actuating device, comprising:
a substrate having a cavity having a first area;
a fixing portion disposed on the substrate;
a first frame disposed around the fixing portion; and
an elastic element connecting the first frame and the fixing portion, and causing the first frame to be suspended above the substrate, wherein:
the first frame has a projecting area onto the substrate; and
the first area and the projecting area have an overlapping portion.

15. The micro-electromechanical actuating device as claimed in claim 14, further comprising:
a first comb finger unit fixed on the fixing portion, and having a first finger direction; and
a first counter comb finger unit disposed on the first frame, and being in pair with the first comb finger unit.

16. The micro-electromechanical actuating device as claimed in claim 15, further comprising:
a decoupling hinge disposed between the first counter comb finger unit and the first frame, connected to the substrate, and immune to a deformation parallel to the first finger direction.

17. The micro-electromechanical actuating device as claimed in claim 16, further comprising:
a constraint hinge connected to and disposed between the substrate and the decoupling hinge, and generating an elastic deformation along the first finger direction.

18. The micro-electromechanical actuating device as claimed in claim 17, wherein:
a first connecting point between the constraint hinge and the decoupling hinge is a decoupling point;
the decoupling point, a second connecting point between the decoupling hinge and the first counter comb finger unit, and a third connecting point between the decoupling hinge and the first frame are aligned in a first straight line; and
the first straight line is parallel to the first finger direction.

19. The micro-electromechanical actuating device as claimed in claim 17, wherein the constraint hinge is connected to a constraint anchor, and connected to the substrate via the constraint anchor.

20. The micro-electromechanical actuating device as claimed in claim 19, wherein a connecting point between the constraint hinge and the decoupling hinge is a decoupling point, and a second straight line formed by linking the constraining anchor with the decoupling point is perpendicular to the first finger direction.
